(19) United States
(12) Patent Application Publication
(10) Pub. No.: US 2012/0043131 A1
(43) Pub. Date: Feb. 23, 2012

(54) Method for Producing a Sensor with Seamless Extrusion Coating of a Sensor Element

(76) Inventors: Nedelco Christov, Koprivnice (CZ); Rostislav Slavik, Koprivnice (CZ)

(21) Appl. No.: 13/148,921

(22) PCT Filed: Feb. 9, 2010
(86) PCT No.: PCT/EP10/51527

§ 371 Date: Nov. 11, 2011

(30) Foreign Application Priority Data
Feb. 11, 2009 (DE) 10-2009-008-457.6

(51) Int. Cl. H01L 23/28; B29C 45/14

(52) U.S. Cl. 174/521; 264/272.15

(57) ABSTRACT

A method for producing a sensor with seamless extrusion coating of a sensor element and a sensor produced by said method. The sensor element is enclosed in as sealed a manner as possible by the extrusion mass, thus permanently preventing the ingress of water, acids, oils or other aggressive materials to the region of the sensor. The method includes inserting the sensor element into a mould cavity, mechanically fixing the sensor element in the mould cavity by at least one movable fixing element that engages the sensor with the mould cavity in a second region of the mould cavity, injection of an extrusion mass into the mould cavity, waiting until the extrusion mass has hardened in a first region of the mould cavity to fix the sensor element in position, removal of the moving fixing element, before the extrusion mass in the second region hardens, such that the still liquid extrusion mass at least partly fills the cavity left in the mould cavity by the removed fixing element.

### CROSS REFERENCE TO RELATED APPLICATION

This is a U.S. national stage of application No. PCT/EP2010/051527, filed on 9 Feb. 2010. Priority is claimed on German Application No.: 10 2009 008 457.6 filed 11 Feb. 2009, the content of which are incorporated here by reference.

### BACKGROUND OF THE INVENTION

The invention relates to a method for producing a sensor with seamless encapsulation of a sensor element and to a sensor produced by this method.

### RELATED ART

It is known to encapsulate sensor elements with plastic materials to protect the sensor element from mechanical damage and from dirt and aggressive environmental influences, such as spray water, spray water with gritting salt, oil, acids, and the like. Especially in the case of applications in automotive engineering, the robustness and durability of sensors have to meet very high requirements. At the same time, the sensors should be very inexpensive and able to be produced in large numbers. Injection molding is a known method in which a sensor element is placed in a mold cavity, after which the hot, liquid injection molding compound is injected into the mold cavity and fills it, the sensor element being enclosed by the injection molding compound. However, the injection molding compound injected at high pressure may displace the sensor element in its position in the mold cavity, which will ultimately lead to a sensor of inferior quality. It is therefore necessary to fix the sensor element in the mold cavity. However, the fixing of the sensor element in the mold cavity results in regions that are not reached by the injection molding compound. These are then filled in a further encapsulation, making seams occur between the first and second encapsulations, representing potential points of weakness through which water, acid, oil, or other aggressive substances from the surroundings of the sensor can penetrate into the sensor. This greatly compromises the durability of the sensor.

It is therefore an object of one embodiment of the invention to provide a method for producing a sensor and a sensor produced by this method with which the sensor element is enclosed as impermeably as possible by the injection molding compound, whereby the penetration of water, acid, oil or other aggressive substances from the surroundings of the sensor into the sensor is prevented with a long-term effect. At the same time, it is intended that the sensor can be produced as inexpensively as possible.

Placing the sensor element in a mold cavity and mechanically fixing the sensor element in the mold cavity by at least one movable fixing element that can engage in the mold cavity in a second region of the mold cavity allows the sensor element to be fixed very exactly in its position in the mold cavity. The fixing is so mechanically stable that the injection molding compound injected later cannot displace the sensor element from its position. As a result, the position of the sensor element in the sensor is maintained very exactly, which leads to sensors of high quality. If, for example, the sensor element is a Hall sensor element, which is intended to detect the change in an external magnetic field, it is of great importance that the sensor element is located exactly at the prescribed position in the sensor. This is ensured with a lasting effect by the fixing element engaging in the mold cavity. When an injection molding compound is injected into the mold cavity, the relative position of the sensor element in the mold cavity remains unchanged. Waiting until the injection molding compound in a first region of the mold cavity has cured to the extent that the injection molding compound that has hardened in the first region fixes the sensor element in its position achieves further fixing of the sensor element that is sufficient for effectively preventing subsequent displacement of the sensor element. This is followed by removal of the fixing element before the injection molding compound located in the second region hardens, so that the still liquid injection molding compound at least partially fills the free space left behind in the mold cavity by the removed fixing element. The fact that the still liquid injection molding compound at least partially fills the free space left behind in the mold cavity by the removed fixing element means that a completely seamless enclosure of the sensor element with the injection molding compound is obtained. After the curing of the injection molding compound, the sensor element consequently has a seamless casing, through which no water, acid, oil, or other aggressive substances from the surroundings of the sensor can penetrate into the sensor.

If a pre-encapsulation of the sensor element is performed before placement of the sensor element in the mold cavity, important functional preconditions for the sensor element can be established. The term pre-encapsulation should be interpreted very broadly here. Pre-encapsulation may also be understood as meaning pre-encasing, for example with a metal or a ceramic compound. This allows, for example, the thermal conductivity to the sensor to be improved, which in the case of temperature sensors, for example, may be of great importance. It is also conceivable for an externally applied magnetic flux to be concentrated toward the sensor element by a pre-encapsulation with a suitable material.

In the case of a development of the invention, with the pre-encapsulation, at least one receiving element for the fixing element is molded onto the sensor element. This achieves particularly good fixing of the sensor element in the mold cavity, which leads to very exact positioning of the sensor element in the sensor. For this purpose, the fixing element may engage in the receiving element and thereby mechanically fix the sensor element until the injection molding compound that has hardened in the first region sufficiently fixes the sensor element in its position.

### BRIEF DESCRIPTION OF THE DRAWINGS

Further features, advantages and developments emerge from the examples explained below in conjunction with the figures, in which:

FIG. 1 is a sensor according to the prior art;

FIG. 2 is a sensor element on a leadframe;

FIG. 3 is the sensor element known from FIG. 2 with the leadframe in a mold cavity’

FIG. 4 is an injection molding compound which has penetrated into the mold cavity under the pressure P;

FIG. 5 is the injection molding compound that has solidified in a first region in the mold cavity;

FIG. 6 is the finished sensor after removal from the mold cavity;

FIG. 7 is the sensor element with the connected leadframe;

FIG. 8 is the sensor element placed in a preliminary mold cavity;

FIG. 9 is the sensor element with the pre-encapsulation in a mold cavity;

FIG. 10 is the injection molding compound injected into the mold cavity under the pressure P;

FIG. 11 is the movable fixing elements withdrawn from the mold cavity;

FIG. 12 is a sensor produced by the method;

FIG. 13 is one particular embodiment of the pre-encapsulation;

FIG. 14 is a sensor with a completely seamless encapsulation of the sensor element;

FIG. 15 is a section through the sensor known from FIG. 14;

FIG. 16 is a further section through a sensor with seamless encapsulation of a sensor element;

FIG. 17 is the sensor known from FIG. 16 from a different perspective; and

FIG. 18 is the principle of removing the movable fixing elements.

### DETAILED DESCRIPTION OF THE PRESENTLY PREFERRED EMBODIMENTS

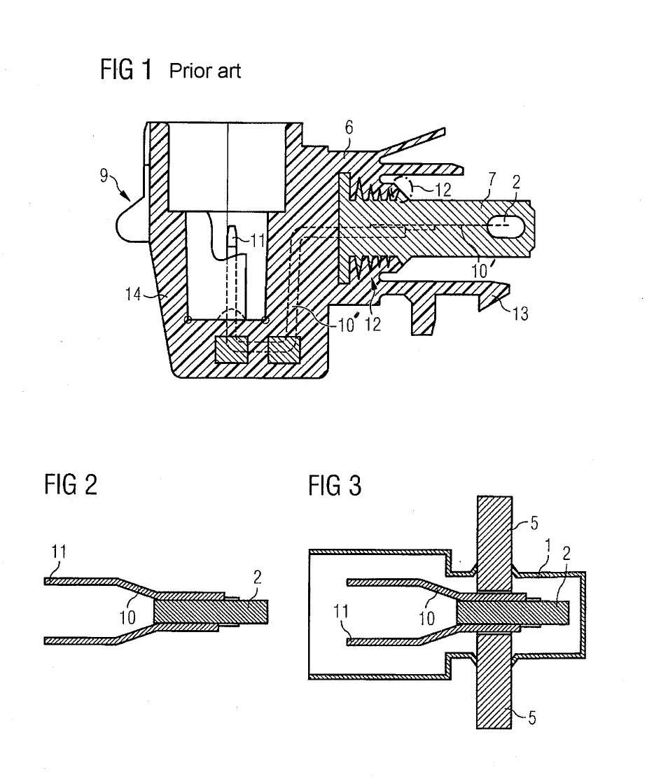

FIG. 1 shows a sensor 9 according to the prior art. This sensor 9 may be, for example, a temperature sensor, in particular an oil temperature sensor, a speed sensor, or some other sensor 9, in which the sensor element 2 must be well protected from the influences of dirt, gaseous, or liquid media. For this purpose, the sensor element 2 is generally pre-encapsulated with a plastic material and a further injection molding compound 6 is molded onto the pre-encapsulation 7. This is necessary because the sensor element 2 is forced out of its position during the injection molding process by the injection molding compound 6 due to the high injection pressure, whereby the position of the sensor element 2 in the pre-encapsulation 7 and in relation to the injection molding compound 6 is inevitably not definitively fixed, which may lead to great inaccuracies in the function of the sensor 9. The sensor element 2 is generally mounted on a leadframe 10′, serving for the mechanical stabilization of the sensor element in the unencapsulated state. After the encapsulation of the sensor element 2 with a plastic material, the leadframe serves for the electrical connection of the sensor element to the downstream evaluation electronics. In addition, evaluation electronics for the sensor element 2 may be placed on the leadframe 10, it likewise being possible for the evaluation electronics to be enclosed by the pre-encapsulation 7 or the injection molding compound 6. The connection to the downstream electronics is ensured by way of the electrical terminal pins 11, which are kept free in the injection molding process. For this purpose, a terminal element 14 is molded from the injection molding compound 6. Also revealed are connecting elements 13, which are likewise molded from the injection molding compound 6 and serve for the mechanical connection of the sensor 9 to other components in the vehicle. It is conceivable, for example, for such a sensor 9 to be formed as a temperature sensor and to be clipped or screwed into a container containing the medium of which the temperature is intended to be measured. It is important in the case of all these sensors 9 that the sensor element 2 is effectively protected from mechanical damage, chemical damage by aggressive media and the penetration of liquids and gases. With respect to the impermeability to the media just mentioned, the connecting region 12 between the pre-encapsulation 7 and the injection molding compound 6 represents a particular point of weakness. Differing temperatures that inevitably act on the sensor 9 during its use may cause thermal stresses to occur in the connecting region 12 between the pre-encapsulation 7 and the injection molding compound 6, with the effect that the connecting region 12 is no longer impermeable, allowing aggressive media to be able to penetrate particularly easily into the sensor 9 at this point. This may lead to the sensor 9 being destroyed. Especially in the area of sensor equipment for motor vehicles, the robustness and durability of such sensors have to meet particularly high demands. It is therefore desirable to produce as few connecting regions 12 as possible, or none at all, between a pre-encapsulation 7 and an injection molding compound 6. Any seam within the injection molding compound 6 or the pre-encapsulation 7, or between the injection molding compound and the pre-encapsulation 7, forms a potential point of weakness into which harmful media can penetrate. It is therefore desirable to produce a sensor 9 that does not have any seams in the cured injection molding compound 6. A method for producing a sensor 9 with seamless encapsulation of a sensor element 2 is represented in FIGS. 2 to 6 and FIGS. 7 to 12.

FIG. 2 shows a sensor element 2, which is mounted on a leadframe 10. The electrical terminal, pins 11 can be seen on the leadframe 10.

In FIG. 3, the sensor element known from FIG. 2 has been placed with the leadframe 10 in a mold cavity 1. The position of the sensor element 2 in the mold cavity 1 is determined by movable fixing elements 5. These movable fixing elements 5 engage through holes in the mold cavity 1 into the interior of the mold cavity 1 and keep the sensor element 2 and the leadframe 10 in the desired position. In FIG. 3, the sensor element 2 is kept exactly on the central axis of symmetry of the mold cavity 1 by the movable fixing elements 5. In FIG. 3, the mold cavity 1 has not yet been injected with injection molding compound 6.

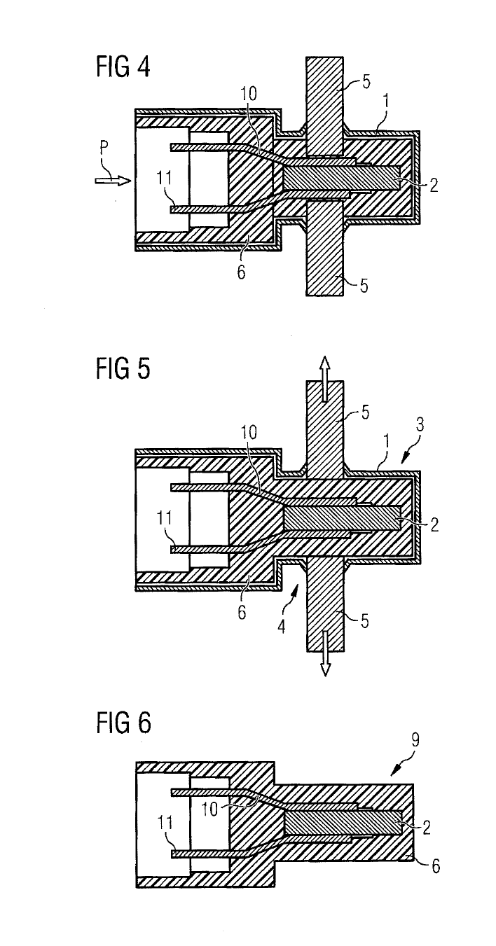

In FIG. 4 it is shown how the injection molding compound 6 has penetrated into the mold cavity 1 under the pressure P, the injection molding compound 6 having enclosed the sensor element 2 and the leadframe 10 in the desired way. In FIG. 4, the injection molding compound 6 is still in the liquid, and consequently warm, state.

FIG. 5 shows how the injection molding compound 6 in the mold cavity 1 has solidified in a first region 3, that is to say has one over from the liquid state into the solid state, or at least into a viscous state, so that the injection molding compound 6 in the first region 3 is capable of mechanically fixing the sensor element 2 and the leadframe 10. Since the injection molding compound 6 in the second region 4 is still in the liquid state, the movable fixing elements 5 can be withdrawn from the still liquid injection molding compound 6 in the second region. The hollow spaces left behind by the movable fixing elements 5 are filled by the still liquid injection molding compound 6. Since, in the first region 3, the injection molding compound 6 has already cured, the sensor element 2 remains in its predetermined position within the mold cavity 1 even after the removal of the movable fixing elements 5. The subsequent flowing of the still liquid injection molding compound 6 into the hollow spaces left behind by the movable fixing elements 5 means that a completely seamless encapsulation of the sensor element 2 and of the leadframe 10 attached thereto is obtained, which can be seen very clearly in FIG. 6.

FIG. 6 shows the finished sensor 9 after removal from the mold cavity 1. It can be seen that the injection molding compound 6 completely and seamlessly encloses the sensor element 2 and the leadframe 10. Merely the electrical terminal pins 11 protrude from the injection molding compound 6. However, it can be ensured by suitable forming of the sensor 9 that no aggressive media occur in the region of the exit points of the electrical terminal pins 11, so that the sensor element 2 is protected by the seamless encapsulation with the injection molding compound 6 with a long-term effect, whereby a durable and inexpensive sensor 9 is provided.

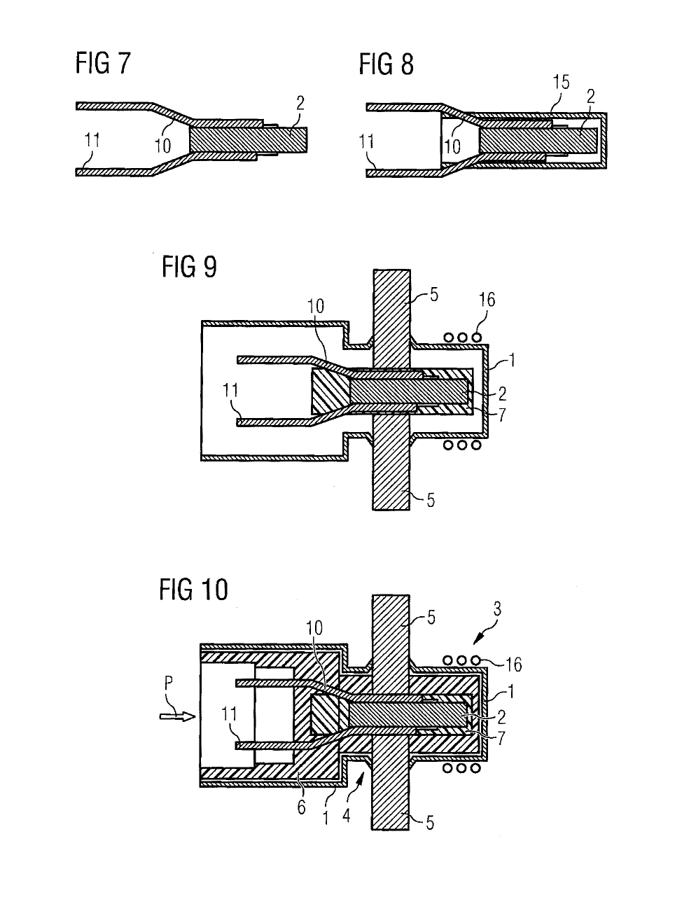

FIGS. 7 to 12 show once again the method according to one embodiment of the invention for producing the sensor 9 with seamless encapsulation of a sensor element 2, a pre-encapsulation 7 being performed here. There may be several reasons for such a pre-encapsulation 7. One is that it is conceivable for only a quite specific material to be allowed to cover the sensor element 2. In addition, it is possible to introduce receiving elements 8 into the pre-encapsulation 7, which is shown FIG. 13. Moreover, it is conceivable for the sensor elements to be surrounded before the actual encapsulation with the injection molding compound 6, for example with a ceramic compound, which then of course does not take place in a customary injection molding process but by pressing and annealing the ceramic compound.

In FIG. 7, the sensor element 2 with the connected leadframe 10 as well as the electrical terminal pins 11 can be seen. In FIG. 8, the sensor element 2 from FIG. 7 has been placed in a preliminary mold cavity 15. An injection molding compound may be injected into this preliminary mold cavity 15, for example, for pre-encapsulation or a ceramic material may be introduced into it, then surrounding the sensor element 2 and parts of the leadframe 10. Then, as represented in FIG. 9, the sensor element 2 prepared in this way is placed with the pre-encapsulation 7 in the mold cavity 1. The sensor element 2 is once again fixed by the movable fixing elements 5, which engage in the mold cavity 1 through clearances in the walls of the mold cavity 1.

FIG. 10 shows how the injection molding compound 6 is injected into the mold cavity 1 under the pressure P, the injection molding compound 6 enclosing the sensor element 2 and the pre-encapsulation 7 as well as parts of the leadframe 10. In the first region 3 of the mold cavity 1, the injected injection molding compound 6 cools down, whereby it becomes solid, or at least viscous, and thereby provides mechanical fixing of the sensor element 2 in the mold cavity. The cooling down of the injection molding compound 6 in the first region 3 of the mold cavity 1 may be assisted by a cooling element 16. It is conceivable for the cooling element 16 in the form of a coolant-carrying pipeline system to be placed around the first region 3 of the mold cavity 1. Cold air or a liquid such as water or oil may be used as the coolant. It is important in this respect that the first region 3 of the mold cavity leads to rapid cooling of the injection molding compound 6, while the injection molding compound 6 is still liquid in the second region 4 of the mold cavity.

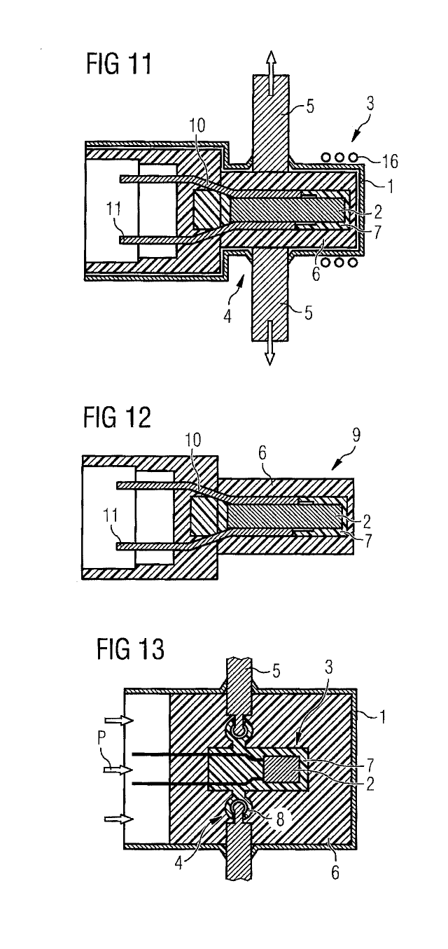

Since the injection molding compound 6 in the first region of the mold cavity 1 has then cooled, and mechanical stabilization of the sensor element 2 in the mold cavity is thereby ensured, the movable fixing elements 5 are withdrawn from the mold cavity 1, which is represented in FIG. 11. Once the movable fixing elements 5 have been withdrawn from the mold cavity 1, the still liquid injection molding compound 6 in the second region 4 of the mold cavity 1 can fill the hollow spaces left behind by the movable fixing elements 5. This leads once again to the production of a sensor 9 with a completely seamless encapsulation of the sensor element 2.

The result of this production method is shown in FIG. 12. This reveals a sensor 9 in which the sensor element 2 and the pre-encapsulation 7 are completely and seamlessly enclosed by the injection molding compound 6. The sensor 9 represented here can be considered to be extremely robust and durable, while it can be produced at very low cost.

FIG. 13 shows one particular embodiment of the pre-encapsulation 7. This reveals once again the mold cavity 1, which is filled with the injection molding compound 6 under the pressure P. The pre-encapsulation 7 now has receiving elements 8, into which the movable fixing elements 5 engage. As a result, particularly secure mechanical fixing of the sensor element 2 in the mold cavity 1 is ensured. Otherwise, the method for producing the sensor 9 as shown in FIG. 13 proceeds analogously to the production of the sensor 9 as shown in FIGS. 7 to 12. After the cooling down of the injection molding compound 6 in the first region 3, the movable fixing elements 5 are removed from the mold cavity 1, being released from their connection with the receiving elements 8. The hollow spaces left behind by the movable fixing elements 5 in the injection molding compound 6 are filled by the still liquid injection molding compound 6 in the second region of the mold cavity 1, once again producing a sensor 9 which has a completely seamless encapsulation of the sensor element 2.

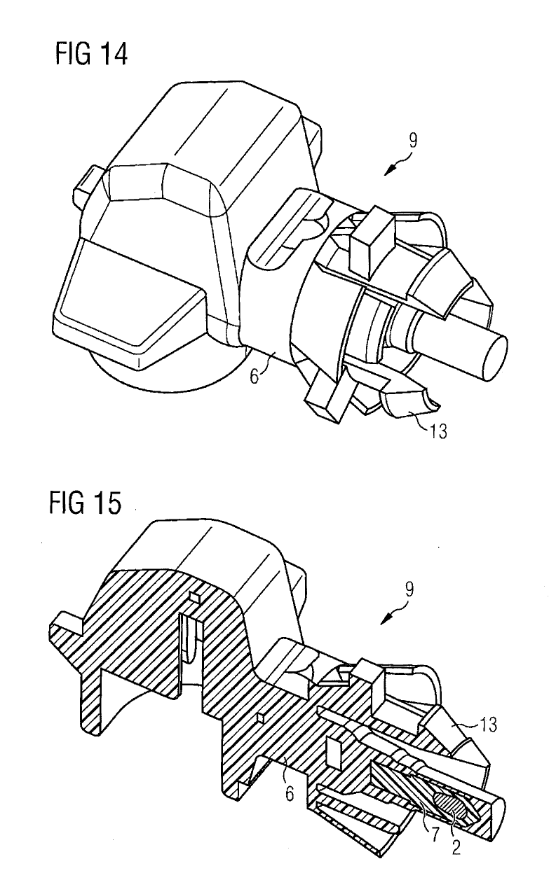

Shown in FIGS. 14 to 18 are sensors 9, which are produced by the method according to the invention for producing a sensor 9 with seamless encapsulation of the sensor element 2.

FIG. 14 shows a sensor 9, which has a completely seamless encapsulation of the sensor element 2, the injection molding compound having formed connecting elements 13 for mechanically connecting the sensor 9, for example to a liquid container.

FIG. 15 shows a section through the sensor 9 known from FIG. 14 with seamless encapsulation of the sensor element 2. It reveals that there are no seams that could lead to the penetration of an aggressive medium into the sensor anywhere in the entire injection molding compound 6.

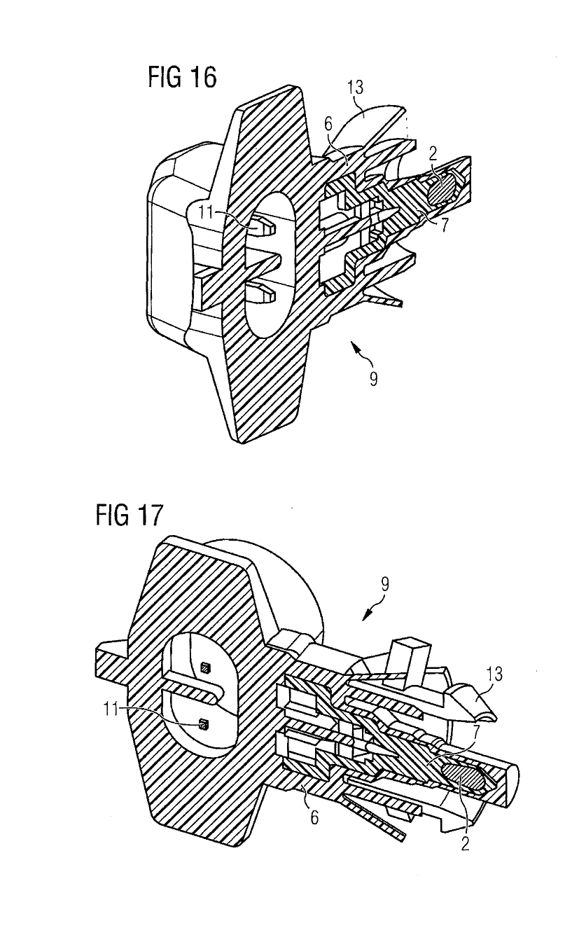

In FIG. 16, a further section through a sensor 9 with seamless encapsulation of a sensor element 2 is represented. Here, the sensor element 2 has a pre-encapsulation 7. This pre-encapsulation 7 is also completely surrounded by the injection molding compound 6, whereby once again no seams are formed at all in the injection molding compound 6. Moreover, FIG. 16 reveals the electrical terminal pins 11 of the sensor 9, which can be protected in a suitable way from aggressive media.

FIG. 17 shows the sensor 9 known from FIG. 16 from a different perspective. It can once again be seen that the sensor element 2 and the pre-encapsulation 7 are completely and seamlessly surrounded by the injection molding compound 6.

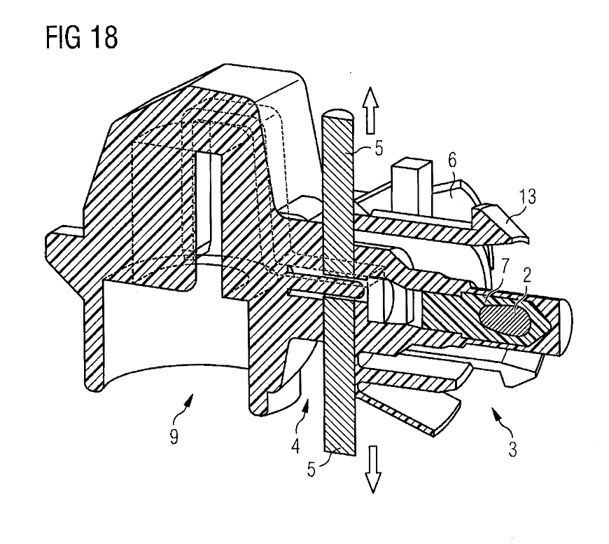

In FIG. 18, the principle of removing the movable fixing elements 5 after the injection of the injection molding compound 6 into the mold cavity 1 is once again represented. Here, too, the already cooled-down injection molding compound 6 in the first region 3 of the mold cavity 1 keeps the sensor element 2 in its position when the movable fixing elements 5 are removed from the mold cavity 1, from the still liquid injection molding compound 6 in the second region thereof. The subsequent flowing of the still liquid injection molding compound 6 into the hollow spaces left behind by the movable fixing elements 5 after their removal produces the desired seamless encapsulation of the sensor element 2 and of the leadframe 10.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-5. (canceled)

6. A method for producing a sensor with seamless encapsulation of a sensor element comprising:
placing the sensor element in a mold cavity having a first and a second region;
mechanically fixing the sensor element in the mold cavity by at least one movable fixing element that engages in the mold cavity in the second region of the mold cavity;
injecting an injection molding compound into the mold cavity;
waiting until the injection molding compound in the first region of the mold cavity has cured such that the injection molding compound in the first region has hardened to fix the sensor element in its position; and
removing the at least one movable fixing element before the injection molding compound located in the second region hardens, so that the injection molding compound at least partially fills a hollow space left behind in the mold cavity when the at least one fixing element is removed.

7. The method for producing the sensor with seamless encapsulation of the sensor element as claimed in claim 6, further comprising pre-encapsulating the sensor element before placement of the sensor element in the mold cavity.

8. The method for producing a sensor with seamless encapsulation of the sensor element as claimed in claim 7, wherein at least one receiving element for the at least one fixing element is molded onto the sensor element with the pre-encapsulation.

9. The method for producing the sensor with seamless encapsulation of the sensor element as claimed in claim 8, further comprising engaging the at least one fixing element in the receiving element and thereby mechanically fixing the sensor element until the injection molding compound has hardened in the first region to fix the sensor element in its position.

10. A sensor component with seamless encapsulation comprising:
a sensor element; and
a seamless encapsulation formed on the sensor element in a mold cavity having a first and a second region by:
the sensor element being fixed in the mold by at least one movable fixing element that engages in the mold cavity in the second region of the mold cavity,
the injection molding compound in the first region fixing the sensor element in its position; and
removing the at least one movable fixing element before the injection molding compound located in the second region hardens, so that the injection molding compound at least partially fills a hollow space left behind in the mold cavity when the at least one fixing element is removed.

11. The sensor with seamless encapsulation as claimed in claim 10, further comprising a pre-encapsulation at least partially encapsulating the sensor element before placement of the sensor element in the mold cavity.

12. The sensor with seamless encapsulation as claimed in claim 11, further comprising at least one receiving element for the at least one fixing element molded onto the sensor element with the pre-encapsulation.

12. The sensor with seamless encapsulation as claimed in claim 11, further comprising a lead frame upon which the sensor element is mounted.
